(19) United States
(12) Patent Application Publication
(10) Pub. No.: US 2012/0126761 A1
(43) Pub. Date: May 24, 2012

(54) CIRCUITRY FOR CONTROLLING A VOLTAGE

(75) Inventor: Charles Derrick Tuten, San Diego, CA (US)

(73) Assignee: QUALCOMM INCORPORATED, San Diego, CA (US)

(21) Appl. No.: 13/298,946

(22) Filed: Nov. 17, 2011

Related U.S. Application Data
(60) Provisional application No. 61/415,856, filed on Nov. 21, 2010.

(51) Int. Cl. G05F 1/10; H03K 17/687

(52) U.S. Cl. 323/271; 327/427

(57) ABSTRACT

Circuitry configured for controlling a voltage is described. The circuitry includes a transient detector that detects a transient in a first frame. The circuitry also includes a controller coupled to the transient detector. The controller determines a duty cycle during a period upon detection of the transient and promotes a second frame based on the period.

### RELATED APPLICATIONS

This application is related to and claims priority from U.S. Provisional Patent Application Ser. No. 61/415,856 filed Nov. 21, 2010, for “FAST TRANSIENT FRAME PROMOTION.”

### TECHNICAL FIELD

The present disclosure relates generally to electronic devices. More specifically, the present disclosure relates to circuitry for controlling a voltage.

### BACKGROUND

In the last several decades, the use of electronic devices has become common. In particular, advances in electronic technology have reduced the cost of increasingly complex and useful electronic devices. Cost reduction and consumer demand have proliferated the use of electronic devices such that they are practically ubiquitous in modern society. As the use of electronic devices has expanded, so has the demand for new and improved features of electronic devices. More specifically, electronic devices that perform functions faster, more efficiently or with higher quality are often sought after. Some examples of electronic devices include circuitry, integrated circuits, processors, computing devices, wireless communication devices, etc.

Electronic devices may use one or more energy sources in order to function. Such energy sources provide electrical power (e.g., voltage, current) in order to enable electronic device functionality. For example, some electronic devices may include processors, integrated circuits, displays, communication interfaces, etc., that require electrical power to function. Some electronic devices use portable energy sources, such as batteries. For instance, a cellular phone may use a battery to function.

An energy source may provide a voltage that varies over time. For example, a battery may provide a voltage. Voltage may vary over time depending on the amount of current being consumed. For instance, when an electronic device consumes a significant amount of current, the voltage provided by a battery may drop. However, some electronic devices may not function properly if the voltage provided varies too much. As can be observed from this discussion, systems and methods that improve voltage regulation may be beneficial.

### SUMMARY

Circuitry configured for controlling a voltage is described. The circuitry includes a transient detector that detects a transient in a first frame. The circuitry also includes a controller coupled to the transient detector. The controller determines a duty cycle during a period upon detection of the transient and promotes a second frame based on the period. The first frame may be truncated to promote the second frame. The controller may perform frame fill-in.

Performing frame fill-in may include generating a control signal based on the transient and the period. Generating the control signal based on the transient and the period may include determining whether the transient is a decreasing transient or an increasing transient.

If the transient is a decreasing transient, then the controller may generate an increase control signal corresponding to the period and driver circuitry may control an input voltage based on the increase control signal. If the transient is an increasing transient, then the controller may generate a decrease control signal corresponding to the period and driver circuitry may control an input voltage based on the decrease control signal.

The circuitry may be coupled to coupling circuitry. The circuitry may control the voltage for a processor. The circuitry may be a buck converter.

A method for controlling a voltage with circuitry is also described. The method includes detecting a transient in a first frame. The method also includes determining a duty cycle during a period upon detection of the transient. The method further includes promoting a second frame based on the period.

A computer-program product for controlling a voltage is also described. The computer-program product includes a non-transitory tangible computer-readable medium with instructions. The instructions include code for causing circuitry to detect a transient in a first frame. The instructions also include code for causing the circuitry to determine a duty cycle during a period upon detection of the transient. The instructions further include code for causing the circuitry to promote a second frame based on the period.

An apparatus for controlling a voltage is also described. The apparatus includes means for detecting a transient in a first frame. The apparatus also includes means for determining a duty cycle during a period upon detection of the transient. The apparatus further includes means for promoting a second frame based on the period.

### BRIEF DESCRIPTION OF THE DRAWINGS

FIG. 1 is a block diagram illustrating one configuration of circuitry in which systems and methods for controlling a voltage may be implemented;

FIG. 2 is a flow diagram illustrating one configuration of a method for controlling a voltage with circuitry;

FIG. 3 is a timing diagram illustrating one example of frame promotion in accordance with the systems and method disclosed herein;

FIG. 4 is a flow diagram illustrating a more specific configuration of a method for controlling a voltage with circuitry;

FIG. 5 is a timing diagram illustrating one example of frame promotion and frame fill-in in accordance with the systems and method disclosed herein;

FIG. 6 is a block diagram illustrating a more specific configuration of circuitry in which systems and methods for controlling a voltage may be implemented;

FIG. 7 is a flow diagram illustrating another more specific configuration of a method for controlling a voltage with circuitry;

FIG. 8 is a diagram illustrating a voltage and one example of how a transient may be detected;

FIG. 9 is a block diagram illustrating one example of voltage regulator circuitry for controlling a voltage for a processor;

FIG. 10 is a block diagram illustrating one configuration of a wireless communication device in which systems and methods for controlling a voltage may be implemented; and

FIG. 11 illustrates various components that may be utilized in an electronic device.

### DETAILED DESCRIPTION

The systems and methods disclosed herein describe controlling a voltage. For example, the systems and methods disclosed herein describe promoting a frame (e.g., “frame promotion) and filling in a frame (e.g., “frame fill-in”) based on a trigger (e.g., detection of a transient). For instance, the systems and methods disclosed herein may provide ways to respond to multiple/repetitive fast current load/unload events (e.g., “transients”).

When a large load is applied at a high attack rate, for instance, a voltage regulator may not respond fast enough, resulting in an output voltage drop. Known solutions bypass or override the proportional integral derivative (PID) loop to quickly bring the voltage back to a target voltage. During override, known solutions do not attempt keep the loop in control. This causes the PID loop to be out of control during the voltage recovery. Depending on how long the recovery takes or how many transients occur in a row, the PID loop can saturate high or low and therefore cause a further voltage excursion when control is returned to the PID loop. Furthermore, when control is returned to the loop, it is lost and may take some time to recover. For a single transient event this may not be a problem, as the loop may be at the required output value and does not have time to deviate very much. However, in the case of multiple and/or repetitive transients, the loop does not have time to recover before the next transient begins and so the loop can move very far from the desired solution.

In some power supplies, there is a control loop that controls the “duty cycle” of a constant frequency switching regulator. A load transient may occur in the middle of the switching frame and the loop may respond by changing the “duty cycle” to prevent a voltage excursion. However, there is a delay until the “new” duty cycle can be implemented. The total delay is the time from transient detection to the start of the next switching frame. This delay may include 2 distinct parts: the time required to calculate the new duty cycle and the time until the next frame starts. In some cases, the delay may be greater than 1 frame (e.g., 1 microsecond (μs) of delay). One challenge addressed by the systems and methods disclosed herein is how to remove this delay and maintain the loop in control.

One approach to alleviate the loop recovery issue is to keep the loop in control. One issue with this approach is that only one PID calculation may occur for each switching cycle (e.g., frame). The delay for this calculation may be longer than allowed by a specified performance level. In order to solve this problem, the systems and methods disclosed herein may immediately perform a new PID calculation, truncate an earlier (e.g., prior, last, etc.) frame and start a new frame (e.g., “frame promotion”). However, this still leaves some time before a regulator output is updated. In some configurations, the systems and methods disclosed herein may additionally override the regulator output with a desired output during the PID calculation (e.g., “frame fill-in”).

Some distinctive features of the systems and methods disclosed herein may include frame promotion and frame fill-in. One example of frame promotion is described hereafter. When a transient is detected, a new solution may be calculated (with more aggressive loop parameters, for example) and a new frame may be started, truncating the prior frame. This new frame sets the timing for following frames until another transient is detected. At that point, the procedure may start all over again.

A time delta may exist between transient detection and the updated loop solution or the beginning of the promoted frame (while the updated loop solution is being calculated, for example). This is where frame fill-in may be used to provide a faster response. Upon the detection of a transient, the gap between transient detection and frame promotion may be “filled in” with a desired voltage (e.g., with 100% or 0% duty cycle), depending on the direction of the transient. The prior frame may be truncated and the following frame may be promoted.

In some configurations, the systems and methods disclosed herein may be implemented as a buck converter that supplies power to a processor. For example, the systems and methods disclosed herein may be implemented as part of a power management integrated circuit (PMIC). However, it should be noted that the systems and methods disclosed herein may be applied to any electronic power supply.

In one configuration, for example, a processor (or other electronic device) may transition from consuming 200 milliamps (mA) to 1.5 amps (A) in 30 nanosecond (ns) while requiring less than a 40 millivolt (mV) maximum power supply voltage dip. The systems and methods disclosed herein may be implemented in new buck converter topologies to meet this challenge, detecting and quickly responding to a load transient.

Various configurations are now described with reference to the Figures, where like reference numbers may indicate functionally similar elements. The systems and methods as generally described and illustrated in the Figures herein could be arranged and designed in a wide variety of different configurations. Thus, the following more detailed description of several configurations, as represented in the Figures, is not intended to limit scope, as claimed, but is merely representative of the systems and methods.

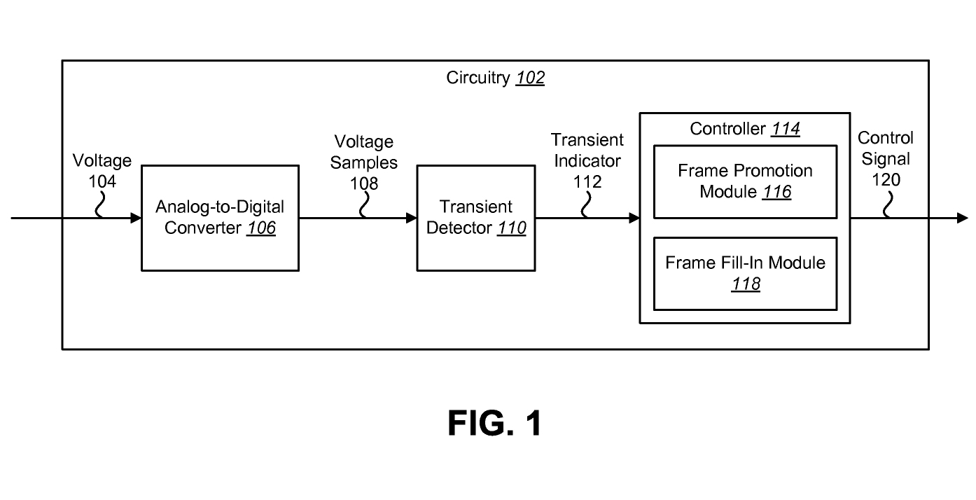

FIG. 1 is a block diagram illustrating one configuration of circuitry 102 in which systems and methods for controlling a voltage may be implemented. The circuitry 102 may be implemented, for example, with one or more components. Examples of components include integrated circuits (ICs), application-specific integrated circuits (ASICs), processors, memory cells, registers, flip-flops, printed circuit boards (PCBs), resistors, capacitors, inductors, transistors, etc.

The circuitry 102 includes an analog-to-digital converter 106 (ADC), a transient detector 110 and a controller 114. The analog-to-digital converter 106 may be coupled to the transient detector 110 and the transient detector 110 may be coupled to the controller 114. The circuitry 102 may receive a voltage 104. The voltage 104 may be a feedback voltage. For example, the circuitry 102 may control the voltage 104 that is fed back to the circuitry 102. The voltage 104 may also be supplied to a load (e.g., a processor).

The voltage 104 may be provided to the analog-to-digital converter 106. The analog-to-digital converter 106 may obtain one or more voltage samples 108 based on the voltage 104 over time. For example, the analog-to-digital converter 106 may quantize the voltage 104 as it varies to obtain one or more voltage samples 108.

The one or more voltage samples 108 may be provided to a transient detector 110. The transient detector 110 may detect a transient. For example, the transient detector 110 may produce a transient indicator 112 based on the voltage samples 108. For instance, the transient detector 110 may determine when the voltage 104 has varied to a particular degree, thereby indicating a transient in the voltage 104. In one configuration, the transient detector 110 may determine whether a voltage sample 108 is beyond a threshold voltage. For example, if a voltage sample 108 differs from a reference voltage by a given amount, the transient detector 110 may produce a transient indicator 112. In another configuration, the transient detector 110 may determine whether a slope corresponding to the voltage samples 108 is beyond a threshold slope. For example, if a slope that is determined based on multiple voltage samples 108 over time is beyond a threshold slope, the transient detector 110 may produce a transient indicator 112.

The controller 114 may generate a control signal 120. In some configurations, the control signal 120 may be provided to driver circuitry that may switch an input voltage on or off as part of a switching voltage regulator. For example, the control signal 120 may indicate a duty cycle. A duty cycle may control the voltage 104 by controlling a proportion of time within the duty cycle when the input voltage is turned on or off. For instance, if an input voltage is 4 volts (V) and a reference voltage (e.g., desired voltage or target voltage) is 1 V, then the controller 114 may produce a control signal 120 that switches the input voltage on for 25% of the duty cycle and off for 75% of the duty cycle. If the voltage 104 decreases below the reference voltage, the controller 114 may increase the proportion of time that the input voltage is switched on (e.g., “on time”) and may decrease the proportion of time that the input voltage is switched off (e.g., “off time”). Conversely, if the voltage 104 increases above the reference voltage, the controller 114 may decrease the “on time” and may increase the “off time.”

It should be noted that the circuitry 102 may operate in accordance with frames. A frame may correspond to a specified amount of time. For example, a frame may be defined in terms of a number of voltage samples 108, clock cycles, analog-to-digital converter 106 (ADC) cycles (e.g., sampling cycles), etc. For example, one frame may comprise 10 ADC or sampling cycles. In some configurations, the controller 114 may normally determine (e.g., calculate or compute) a duty cycle once per frame (which may be reflected by the control signal 120, for example).

In some cases, the voltage 104 may vary rapidly enough that typical control may not be sufficient to maintain the voltage 104 within a specified range. Such variations in voltage 104 may be referred to as “transients” or “fast transients” herein.

The controller 114 may include a frame promotion module 116. The controller 114 may optionally include a frame fill-in module 118. In other words, the controller 114 may not include a frame fill-in module 118 in some configurations. The frame promotion module 116 and/or the frame fill-in module 118 may reduce the impact of transients (e.g., an amount of voltage dip or voltage spike). It should be noted that the frame promotion module 116 and/or the frame fill-in module 118 may be implemented in hardware, software or a combination of both.

The frame promotion module 116 may promote a frame in response to a transient indicator 112. For example, the frame promotion module 116 may truncate a first frame and promote a second frame. As described above, the controller 114 may typically determine a duty cycle once per frame. In some configurations, the controller 114 may normally determine a duty cycle at the normal end of a frame, before transitioning to a subsequent frame. However, the frame promotion module 116 may cause the controller 114 to determine the duty cycle during a period that is earlier than normal in a frame (e.g., at the beginning or middle of a frame) upon receiving the transient indicator 112. The first frame may be truncated at the end of the period and the second frame may be promoted to begin at the end of the period. This may allow the controller 114 to respond more rapidly to transients while maintaining control.

In some configurations, the frame fill-in module 118 may generate the control signal 120 based on the transient and the period. For example, when the controller 114 receives a transient indicator 112, the frame promotion module 116 may promote the subsequent frame to start approximately at the end of the period in which the controller 114 determines a duty cycle as described above. The frame fill-in module 118 may generate the control signal 120 in order to respond to the transient based on the transient and the period. For example, if the transient is a dip in the voltage 104, the frame fill-in module 118 may cause the controller 114 to generate a control signal 120 that switches the input voltage on within (e.g., during all or part of) the period and/or after the period. Additionally or alternatively, if the transient is a spike in the voltage 104, the frame fill-in module 118 may cause the controller 114 to generate a control signal 120 that switches the input voltage off within (e.g., during all or part of) the period and/or after the period. More generally, the frame fill-in module 118 may cause the controller 114 to generate a control signal 120 with increased “on time” for a voltage dip or no increased “on time” (e.g., increased “off time”) for a voltage spike.

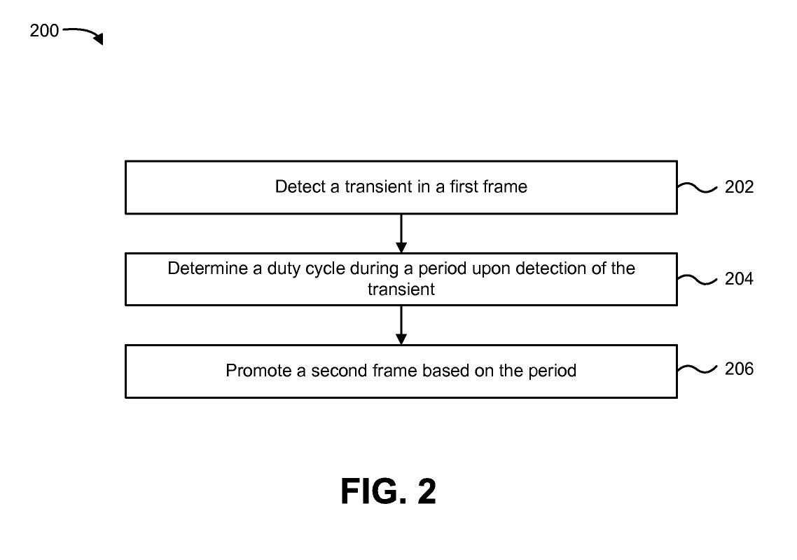

FIG. 2 is a flow diagram illustrating one configuration of a method 200 for controlling a voltage 104 with circuitry 102. The circuitry 102 may detect 202 a transient in a first frame. For example, the circuitry 102 may determine when the voltage 104 has varied to a particular degree, thereby indicating a transient in the voltage 104. In one configuration, the circuitry 102 may determine whether a voltage sample 108 is beyond a threshold voltage. For example, if a voltage sample 108 differs from a reference voltage by a given amount, the circuitry 102 may detect 202 a transient. In another configuration, the circuitry 102 may determine whether a slope based on the voltage 104 is beyond a threshold slope. For example, if a slope that is determined based on the voltage 104 over time is beyond a threshold slope, the circuitry 102 may detect 202 a transient.

The circuitry 102 may determine 204 a duty cycle during a period upon detection 202 of the transient. For example, approximately when the transient is detected 202 (e.g., when a transient indicator 112 is received by the controller 114), the circuitry 102 may begin determining 204 a duty cycle during a period. The period may be an amount of time (e.g., a number of clock cycles or a number of analog-to-digital converter 106 sampling cycles) within which the duty cycle may be determined 204 (e.g., calculated, computed, etc.).

The circuitry 102 may promote 206 a second frame based on the period. For example, the circuitry 102 may promote 206 the second frame (e.g., a frame that follows the first frame) to start at the end of the period. For instance, the start of the second frame may approximately coincide with the end of the period. Accordingly, the first frame may be truncated (e.g., shortened compared to a normal frame) and the second frame may begin earlier than if the transient had not occurred.

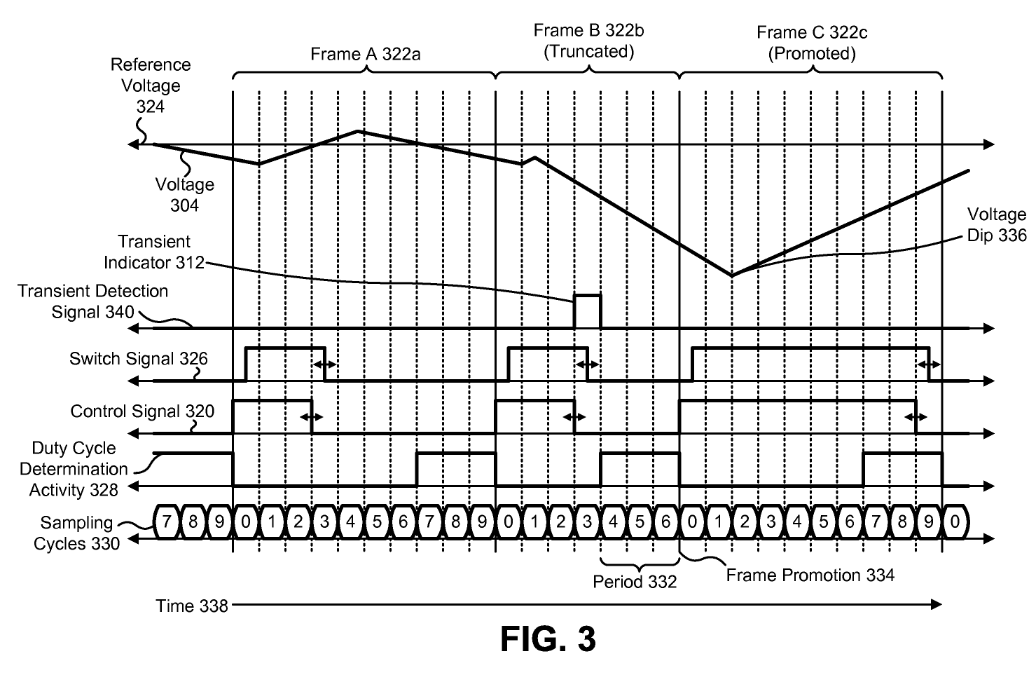

FIG. 3 is a timing diagram illustrating one example of frame promotion in accordance with the systems and method disclosed herein. In particular, FIG. 3 illustrates one example of the signal and/or operation timing on circuitry 102 over time 338. In this example, circuitry 102 operations may occur in accordance with sampling cycles 330. For example, each sampling cycle 330 may be an amount of time for the analog-to-digital converter 106 to produce another voltage sample 108. However, in other configurations, circuitry 102 operations may occur in accordance with clock cycles, amounts of time or other time quanta.

In this example, the circuitry 102 (e.g., controller 114) may determine a duty cycle for a following frame when duty cycle determination activity 328 is high. For instance, the duty cycle for frame A 322a may be determined prior to frame A 322a. This duty cycle for frame A 322a may be reflected or indicated by a control signal 320 and/or a switch signal 326. For example, the control signal 320 may go high for a proportion of frame A 322a (during “on time,” for instance) and may go low for a proportion of frame A 322a (during “off time,” for instance). In frame A 322a, the control signal 320 is high for three sampling cycles 330 and low for seven sampling cycles 330. In some configurations, a switch signal 326 may be an input voltage as it is switched on and off over time 338. The switch signal 326 may correspond to the control signal 320. As illustrated in FIG. 3, a switch signal 326 may be delayed compared to the control signal 320 (on account of propagation delay, for example).

In this example, a voltage 304 is illustrated (in relation to a reference voltage 324). As shown in FIG. 3, the voltage 304 may vary over time 338 and may decrease to a voltage dip 336. In frame A 322a, no transients occur and the circuitry 102 may operate normally. In frame B 322b, a transient may occur. In this case, the transient is a drop in voltage 304. In frame B 322b, a transient detection signal 340 may include a transient indicator 312 when the transient is detected. For instance, the transient detector 110 may produce the transient indicator 312.

When the transient indicator 312 occurs in frame B 322b, duty cycle determination activity 328 may go high during a period 332. For example, the controller 114 may receive the transient indicator 312 and respond by determining a duty cycle during the period 332 that follows the transient indicator 312. As shown in FIG. 3, the transient indicator 312 may occur in the middle of frame B 322b and the duty cycle for frame C 322c may be determined during the period 332, which may be earlier than if no transient had occurred.

Frame C 322c may be promoted to start at the end of the period 332 (e.g., when the duty cycle has been determined by the controller 114 or the duty cycle determination activity 328 goes low). In other words, frame promotion 334 may occur approximately at the end of the period 332. For example, the controller 114 may truncate frame B 322b (e.g., a first frame) and may promote frame C 322c (e.g., a second frame). The duty cycle determined during the period 332 may be applied at the beginning of frame C 322c. As illustrated in FIG. 3, the control signal 320 and the switch signal 326 may thus go high in response to the transient. As a result, the voltage 304 may recover from the transient at the voltage dip 336. By promoting a frame, for example, the circuitry 102 may respond more quickly to transients, which may result in a reduced voltage dip or a reduced voltage spike. It should be noted that if the transient were a voltage spike instead of a voltage dip 336, the duty cycle determined during the period 332 may have reduced the amount of time the control signal 320 would be high (e.g., “on time”) in frame C 322c, thereby reducing the voltage spike.

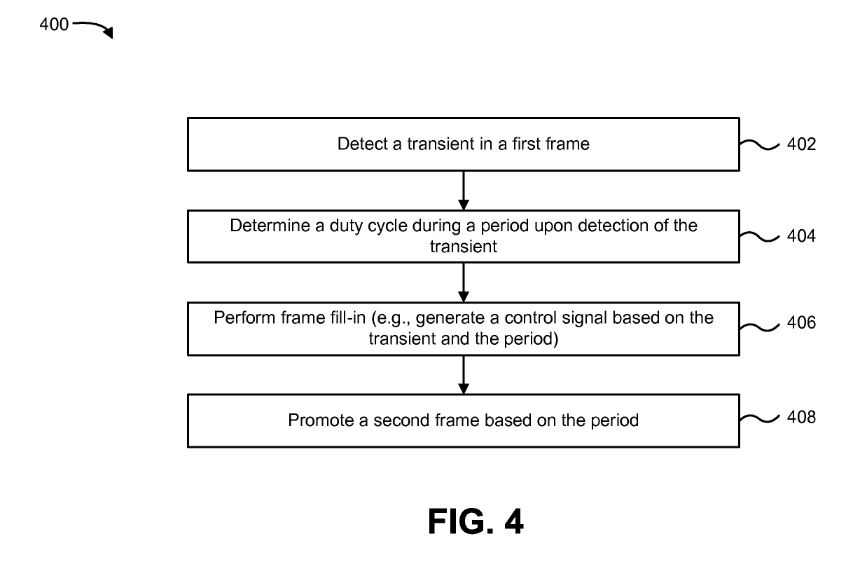

FIG. 4 is a flow diagram illustrating a more specific configuration of a method 400 for controlling a voltage 104 with circuitry 102. The circuitry 102 may detect 402 a transient in a first frame. For example, the circuitry 102 may determine when the voltage 104 has varied to a particular degree, thereby indicating a transient in the voltage 104. In one configuration, the circuitry 102 may determine whether a voltage sample 108 is beyond a threshold voltage. For example, if a voltage sample 108 differs from a reference voltage by a given amount, the circuitry 102 may detect 402 a transient. In another configuration, the circuitry 102 may determine whether a slope based on the voltage 104 is beyond a threshold slope. For example, if a slope that is determined based on the voltage 104 over time is beyond a threshold slope, the circuitry 102 may detect 402 a transient.

The circuitry 102 may determine 404 a duty cycle during a period upon detection 402 of the transient. For example, approximately when the transient is detected 402 (e.g., when a transient indicator 112 is received by the controller 114), the circuitry 102 may begin determining 404 a duty cycle during a period. The period may be an amount of time (e.g., a number of clock cycles or a number of analog-to-digital converter 106 sampling cycles) within which the duty cycle may be determined 404 (e.g., calculated, computed, etc.).

The circuitry 102 may perform 406 frame fill-in. For example, the circuitry 102 may generate 406 a control signal 120 based on the transient and the period. For example, the circuitry 102 may generate 406 a control signal 120 that corresponds to the period. The control signal 120 may approximately coincide with the period. For instance, the control signal 120 may respond to the transient for the remainder of the first frame. This may be referred to as “frame fill-in.” In some configurations, the control signal 120 generated 406 or other signals (e.g., a switch signal) based on the controls signal 120 may continue into a portion of the second frame.

The control signal 120 may be generated 406 based on the transient. For example, if the transient is an increase in voltage 104 (e.g., a voltage spike), then the control signal 120 may switch an input voltage off or reduce the amount of “on time.” Conversely, if the transient is a decrease in voltage 104 (e.g., a voltage dip), then the control signal 120 may switch an input voltage on or increase the amount of “on time.”

The circuitry 102 may promote 408 a second frame based on the period. For example, the circuitry 102 may promote 408 the second frame (e.g., a frame the follows the first frame) to start at the end of the period. For instance, the start of the second frame may approximately coincide with the end of the period. Accordingly, the first frame may be truncated (e.g., shortened compared to a normal frame) and the second frame may begin earlier than if the transient had not occurred.

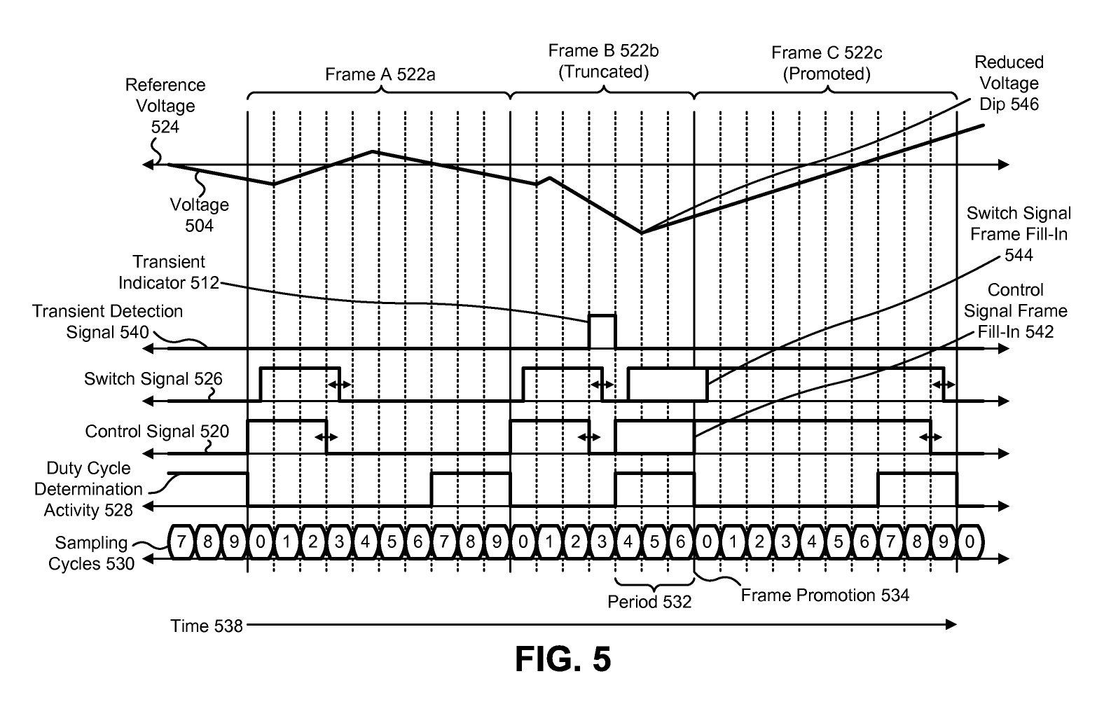

FIG. 5 is a timing diagram illustrating one example of frame promotion and frame fill-in in accordance with the systems and method disclosed herein. In particular, FIG. 5 illustrates one example of the signal and/or operation timing on circuitry 102 over time 538. In this example, circuitry 102 operations may occur in accordance with sampling cycles 530. For example, each sampling cycle 530 may be an amount of time for the analog-to-digital converter 106 to produce another voltage sample 108. However, in other configurations, circuitry 102 operations may occur in accordance with clock cycles, amounts of time or other time quanta.

In this example, the circuitry 102 (e.g., controller 114) may determine a duty cycle for a following frame when duty cycle determination activity 528 is high. For instance, the duty cycle for frame A 522a may be determined prior to frame A 522a. This duty cycle for frame A 522a may be reflected or indicated by a control signal 520 and/or a switch signal 526. For example, the control signal 520 may go high for a proportion of frame A 522a (during “on time,” for instance) and may go low for a proportion of frame A 522a (during “off time,” for instance). In frame A 522a, the control signal 520 is high for three sampling cycles 530 and low for seven sampling cycles 530. In some configurations, a switch signal 526 may be an input voltage as it is switched on and off over time 538. The switch signal 526 may correspond to the control signal 520. As illustrated in FIG. 5, a switch signal 526 may be delayed compared to the control signal 520 (on account of propagation delay, for example).

In this example, a voltage 504 is illustrated (in relation to a reference voltage 524). As shown in FIG. 5, the voltage 504 may vary over time 538 and may decrease to a reduced voltage dip 546. In frame A 522a, no transients occur and the circuitry 102 may operate normally. In frame B 522b, a transient may occur. In this case, the transient is a drop in voltage 504. In frame B 522b, a transient detection signal 540 may include a transient indicator 512 when the transient is detected. For instance, the transient detector 110 may produce the transient indicator 512.

When the transient indicator 512 occurs in frame B 522b, duty cycle determination activity 528 may go high during a period 532. For example, the controller 114 may receive the transient indicator 512 and respond by determining a duty cycle during the period 532 that follows the transient indicator 512. As shown in FIG. 5, the transient indicator 512 may occur in the middle of frame B 522b and the duty cycle for frame C 522c may be determined during the period 532, which may be earlier than if no transient had occurred.

The control signal 520 (approximately from the transient indicator 512 to the end of frame B 522b, for example) may be generated based on the transient and the period 532 in response to the transient indicator 512. For example, the circuitry 102 may perform frame fill-in that corresponds to the period 532. For instance, control signal frame fill-in 542 may be generated based on the period 532 and the transient. The control signal frame fill-in 542 may approximately coincide with the period 532. For instance, the control signal 520 may respond to the transient for the remainder of frame B 522b. Additionally or alternatively, switch signal frame fill-in 544 may approximately coincide with the period 532. In the example illustrated in FIG. 5, the switch signal frame fill-in 544 is slightly delayed in relation to the period 532 (and/or the control signal frame fill-in 542). The switch signal frame fill-in 544 may continue into a portion of frame C 522c.

The control signal 520 (approximately from the transient indicator 512 to the end of frame B 522b, for example) may be generated based on the transient. If the transient is a decrease in voltage 504 (e.g., a voltage dip) as illustrated in FIG. 5, then the control signal 520 may switch an input voltage on or increase the amount of “on time.” For example, the control signal 520 may cause a corresponding switch signal 526 to be generated, for instance). However, if the transient is an increase in voltage 504 (e.g., a voltage spike), then the control signal 520 may switch (or maintain) an input voltage off or reduce the amount of “on time” (by causing a corresponding switch signal 526 to be generated, for instance).

Frame C 522c may be promoted to start at the end of the period 532 (e.g., when the duty cycle has been determined by the controller 114 or the duty cycle determination activity 528 goes low). In other words, frame promotion 534 may occur approximately at the end of the period 532. For example, the controller 114 may truncate frame B 522b (e.g., a first frame) and may promote frame C 522c (e.g., a second frame). The duty cycle determined during the period 532 may be applied at the beginning of frame C 522c. As illustrated in FIG. 5, the control signal 520 and the switch signal 526 may thus go high in response to the transient. As a result of the frame promotion 534 and the frame fill-in (e.g., the control signal frame fill-in 542 and/or the switch signal frame fill-in 544), the voltage 504 may recover from the transient at the reduced voltage dip 546. By promoting a frame and performing frame fill-in, for example, the circuitry 102 may respond more quickly to transients, which may result in a reduced voltage dip 546 or a reduced voltage spike. It should be noted that if the transient were a voltage spike instead of a reduced voltage dip 546, the duty cycle determined during the period 532 may have reduced the amount of time the control signal 520 would be high (e.g., “on time”) in frame C 522c, thereby reducing the voltage spike.

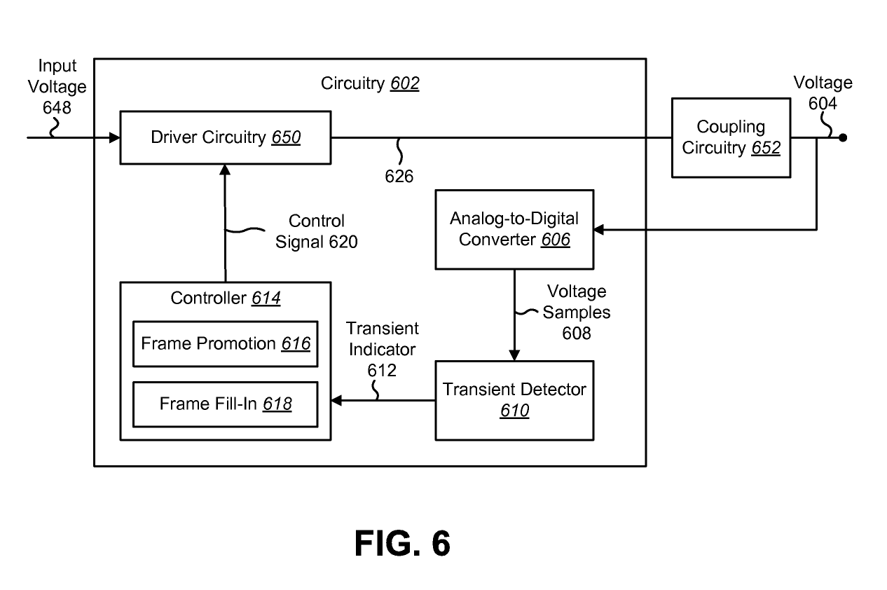

FIG. 6 is a block diagram illustrating a more specific configuration of circuitry 602 in which systems and methods for controlling a voltage may be implemented. The circuitry 602 may be one example of the circuitry 102 described above in connection with FIG. 1.

The circuitry 602 includes an analog-to-digital converter 606 (ADC), a transient detector 610, a controller 614 and driver circuitry 650. The circuitry 602 may receive a voltage 604. The voltage 604 may be a feedback voltage. For example, the circuitry 602 may control the voltage 604 that is fed back to the circuitry 602. The voltage 604 may also be provided to a load (e.g., a processor).

The voltage 604 may be provided to the analog-to-digital converter 606. The analog-to-digital converter 606 may obtain one or more voltage samples 608 based on the voltage 604 over time. For example, the analog-to-digital converter 606 may quantize the voltage 604 as it varies to obtain one or more voltage samples 608.

The one or more voltage samples 608 may be provided to a transient detector 610. The transient detector 610 may detect a transient. For example, the transient detector 610 may produce a transient indicator 612 similarly to the transient detector 110 described above in connection with FIG. 1.

The controller 614 may generate a control signal 620. The control signal 620 may be provided to driver circuitry 650 that may switch an input voltage 648 on or off as part of a switching voltage regulator. For example, the control signal 620 may indicate a duty cycle. A duty cycle may control the voltage 604 by controlling a proportion of time within the duty cycle when the input voltage is turned on or off. If the voltage 604 decreases below the reference voltage, the controller 614 may increase the proportion of time that the input voltage is switched on (e.g., “on time”) and may decrease the proportion of time that the input voltage is switched off (e.g., “off time”). Conversely, if the voltage 604 increases above the reference voltage, the controller 614 may decrease the “on time” and may increase the “off time.”

The controller 614 may include a frame promotion module 616. The controller 614 may optionally include a frame fill-in module 618. In other words, the controller 614 may not include a frame fill-in module 618 in some configurations. The frame promotion module 616 and/or the frame fill-in module 618 may reduce the impact of transients (e.g., an amount of voltage dip or voltage spike). It should be noted that the frame promotion module 616 and/or the frame fill-in module 618 may be implemented in hardware, software or a combination of both.

The frame promotion module 616 may promote a frame in response to a transient indicator 612. For example, the frame promotion module 616 may truncate a first frame and promote a second frame. The controller 614 may typically determine a duty cycle once per frame. In some configurations, the controller 614 may normally determine a duty cycle at the normal end of a frame, before transitioning to a subsequent frame. However, the frame promotion module 616 may cause the controller 614 to determine the duty cycle during a period that is earlier than normal in a frame (e.g., at the beginning or middle of a frame) upon receiving the transient indicator 612. The first frame may be truncated at the end of the period and the second frame may be promoted to begin at the end of the period. This may allow the controller 614 to respond more rapidly to transients while maintaining control.

In some configurations, the frame fill-in module 618 may generate the control signal 620 based on the transient and the period. For example, when the controller 614 receives a transient indicator 612, the frame promotion module 616 may promote the subsequent frame to start approximately at the end of the period in which the controller 614 determines a duty cycle as described above. The frame fill-in module 618 may generate the control signal 620 in order to respond to the transient based on the transient and the period. For example, if the transient is a dip in the voltage 604, the frame fill-in module 618 may cause the controller 614 to generate a control signal 620 that switches the input voltage on within (e.g., during all or part of) the period and/or after the period. Additionally or alternatively, if the transient is a spike in the voltage 604, the frame fill-in module 618 may cause the controller 614 to generate a control signal 620 that switches the input voltage off within (e.g., during all or part of) the period and/or after the period. More generally, the frame fill-in module 618 may cause the controller 614 to generate a control signal 620 with increased “on time” for a voltage dip or no increased “on time” (e.g., increased “off time”) for a voltage spike.

The driver circuitry 650 may switch the input voltage 648 on and/or off during a duty cycle based on the control signal 620. The output of the driver circuitry 650 may be a switch signal 626 (e.g., the input voltage 648 that is switched on and/or off during a duty cycle) that may be provided to the coupling circuitry 652. The coupling circuitry 652 may couple the circuitry 602 to the voltage 604. For example, the coupling circuitry 652 may couple the circuitry 602 to a load and provide the voltage 604 to the load. One example of the coupling circuitry 652 includes an inductor and a capacitor. For instance, the coupling circuitry 652 may function as a low-pass filter in some configurations.

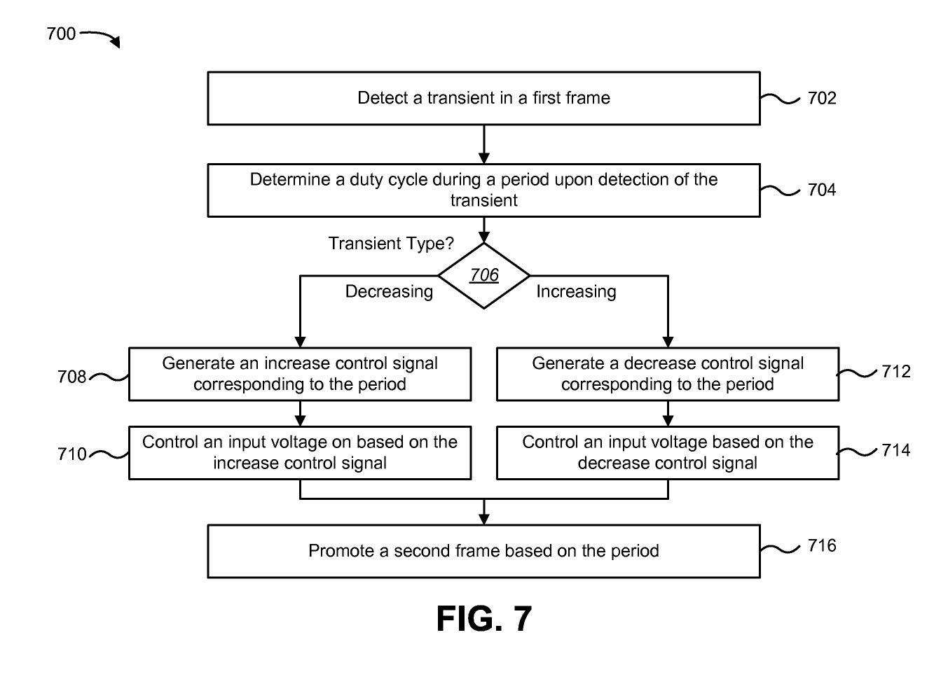

FIG. 7 is a flow diagram illustrating another more specific configuration of a method 700 for controlling a voltage 604 with circuitry 602. The circuitry 602 may detect 702 a transient in a first frame. For example, the circuitry 602 may determine when the voltage 604 has varied to a particular degree, thereby indicating a transient in the voltage 604. In one configuration, the circuitry 602 may determine whether a voltage sample 608 is beyond a threshold voltage. For example, if a voltage sample 608 differs from a reference voltage by a given amount, the circuitry 602 may detect 702 a transient. In another configuration, the circuitry 602 may determine whether a slope based on the voltage 604 is beyond a threshold slope. For example, if a slope that is determined based on the voltage 604 over time is beyond a threshold slope, the circuitry 602 may detect 702 a transient.

The circuitry 602 may determine 704 a duty cycle during a period upon detection 702 of the transient. For example, approximately when the transient is detected 702 (e.g., when a transient indicator 612 is received by the controller 614), the circuitry 602 may begin determining 704 a duty cycle during a period. The period may be an amount of time (e.g., a number of clock cycles or a number of analog-to-digital converter 606 sampling cycles) within which the duty cycle may be determined 704 (e.g., calculated, computed, etc.).

The circuitry 602 may perform frame fill-in. In some configurations, frame fill-in may be performed as follows. The circuitry 602 may determine 706 a transient type. For instance, the circuitry 602 may determine 706 whether the transient is increasing (e.g., a spike) or is decreasing (e.g., a dip). For instance, if the voltage 604 is increasing, the circuitry 602 may determine an increasing transient type. However, if the voltage 604 is decreasing, the circuitry 602 may determine a decreasing transient type. In some configurations, the circuitry 602 (e.g., controller 614) may determine 706 the transient type based on the sign of a slope. For example, in the case where the analog-to-digital converter 606 is a non-window ADC, if the least significant bit (LSB) is 11 mV and the circuitry 602 is operating with a voltage 604 of 1.1 volts (V), the ADC may output a code of 100. In this example, an 11 mV increase may correspond to a code of 101. Thus, (101−100)=+1/time for a positive slope. However, if the voltage 604 decreased 11 mV, then the ADC may output a code of 99. Thus, (99−100)=−1/time for a negative slope. In another example, in the case where the analog-to-digital converter 606 is a window ADC, 1.1 V may correspond to a code 0, plus 5.5 mV may correspond to a code +1 and minus 5.5 mV may correspond to a code −1.

If the transient is a decreasing transient, the circuitry 602 may generate 708 an increase control signal 620 corresponding to the period. For example, the circuitry 602 (e.g., controller 614) may generate (e.g., switch or maintain) 708 a control signal 620 to indicate that the input voltage 648 will be maintained on, will be switched on or will be switched on for more time than currently anticipated (based on the current duty cycle) for a portion (e.g., the remainder) of the first frame and/or for a portion of the second frame. The increase control signal 620 generated 708 may approximately coincide with the period.

The circuitry 602 may control 710 an input voltage 648 based on the increase control signal 620. For example, the circuitry 602 (e.g., driver circuitry 650) may maintain the input voltage 648 on, switch the input voltage 648 on or switch the input voltage 648 on for more time than currently anticipated (based on the current duty cycle) for a portion (e.g., the remainder) of the first frame and/or for a portion of the second frame.

If the transient is an increasing transient, the circuitry 602 may generate 712 a decrease control signal 620 corresponding to the period. For example, the circuitry 602 (e.g., controller 614) may generate (e.g., switch or maintain) 712 a control signal 620 to indicate that the input voltage 648 will be maintained off, will be switched off or will be switched on for less time than currently anticipated (based on the current duty cycle) for a portion (e.g., the remainder) of the first frame and/or for a portion of the second frame. The decrease control signal 620 generated 712 may approximately coincide with the period.

The circuitry 602 may control 714 an input voltage 648 based on the decrease control signal 620. For example, the circuitry 602 (e.g., driver circuitry 650) may maintain the input voltage 648 off, switch the input voltage 648 off or switch the input voltage 648 on for less time than currently anticipated (based on the current duty cycle) for a portion (e.g., the remainder) of the first frame and/or for a portion of the second frame.

The circuitry 602 may promote 716 a second frame based on the period. For example, the circuitry 602 may promote 716 the second frame (e.g., a frame that follows the first frame) to start at the end of the period. For instance, the start of the second frame may approximately coincide with the end of the period. Accordingly, the first frame may be truncated (e.g., shortened compared to a normal frame) and the second frame may begin earlier than if the transient had not occurred. The circuitry 602 may promote 716 the second frame whether the transient type is decreasing or increasing.

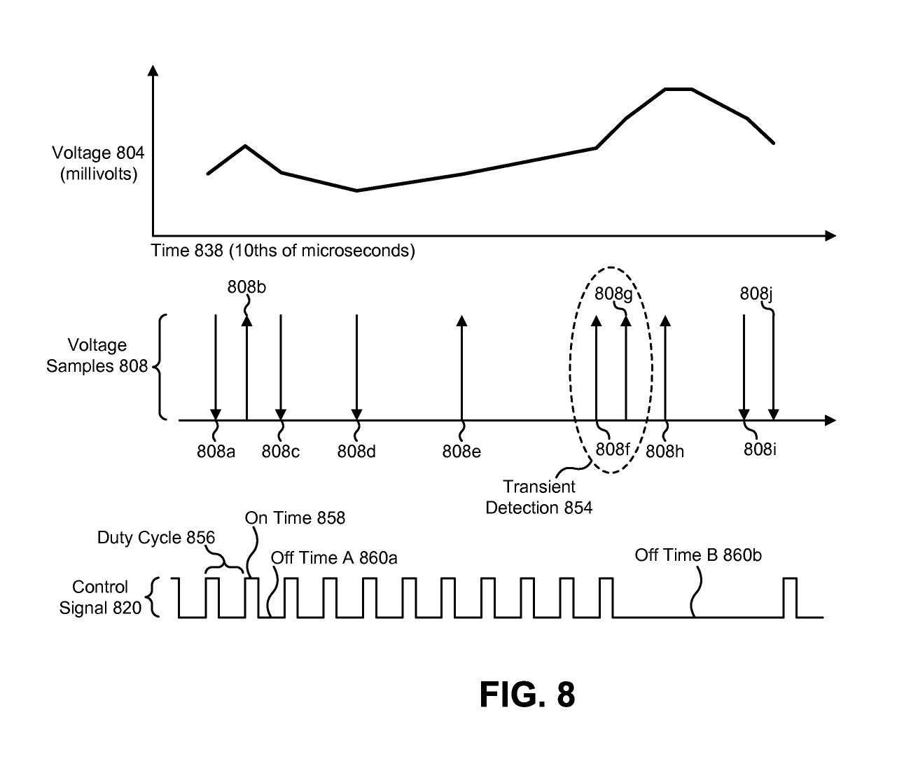

FIG. 8 is a diagram illustrating a voltage 804 and one example of how a transient may be detected. The voltage 804 (illustrated in millivolts, for example) may vary over time 838 (illustrated in 10^{ths} of microseconds, for example) as illustrated.

Variations in the voltage 804 may be caused by a variety of factors. Examples of voltage 804 variations include noise, fast load transients, slow load transients, etc. Voltage samples 808 of the voltage 804 may be taken over time 838. The voltage samples 808a-j illustrated may only be some of the voltage samples taken over time 838.

The first three voltage samples 808a-c illustrated may correspond to a voltage variation due to noise. In one configuration, positive and negative slope thresholds for transient detection may be configured so that voltage variations due to noise may not exceed the slope thresholds. In other words, the threshold rates of change (e.g., positive and negative slopes) may be selected to filter out voltage variations due to noise. The third and fourth voltage samples 808c-d may correspond to a voltage variation drop over an extended a period of time 838. In this case, the slope corresponding with the third and fourth voltages samples 808c-d may not exceed the negative slope threshold. The fifth voltage sample 808e may indicate an increase in voltage 804. However, the increase in voltage 804 may not exceed the positive slope threshold.

The sixth and seventh voltage samples 808f-g may correspond to a voltage variation due to a transient (e.g., a fast unload transient). As illustrated, the sixth and seventh voltage samples 808f-g may correspond to a sufficient change in the voltage 804 over time 838 to exceed the positive slope threshold and result in a transient detection 854.

As illustrated, a control signal 820 may include a series of pulses (for driving driver circuitry 650 as illustrated in FIG. 6, for example). The control signal 820 may include one or more duty cycles 856. A duty cycle 856 may include an amount of on time and/or an amount of off time. For example, one duty cycle may include on time 858 and off time A 860a. For instance, a 30% duty cycle may include on time 858 for 30% of the cycle time and off time A 860a for 70% of the cycle time. In response to a transient detection 854, the control signal 820 may indicate reduced on time (e.g., no on time) or off time B 860b. Upon transient detection 854, circuitry 102 (e.g., a controller 114) may promote a following frame (e.g., frame promotion) and may optionally perform frame fill-in. In this example, this may provide a rapid response to the transient as illustrated by off time B 860b.

As illustrated in FIG. 8, an eighth voltage sample 808h may still indicate an increase in voltage 804, although with a lesser positive slope. Eventually, the voltage 804 may decrease as illustrated by the ninth and tenth voltage samples 808i-j. For example, the circuitry 102 may recovery from a voltage spike. The circuitry 102 (e.g., controller 114) may continue to control the voltage 804 through the response to the voltage spike. In a different scenario (e.g., a voltage dip), the circuitry 102 (e.g., controller 114) may increase the on time through frame promotion and optional frame fill-in to properly respond to the transient.

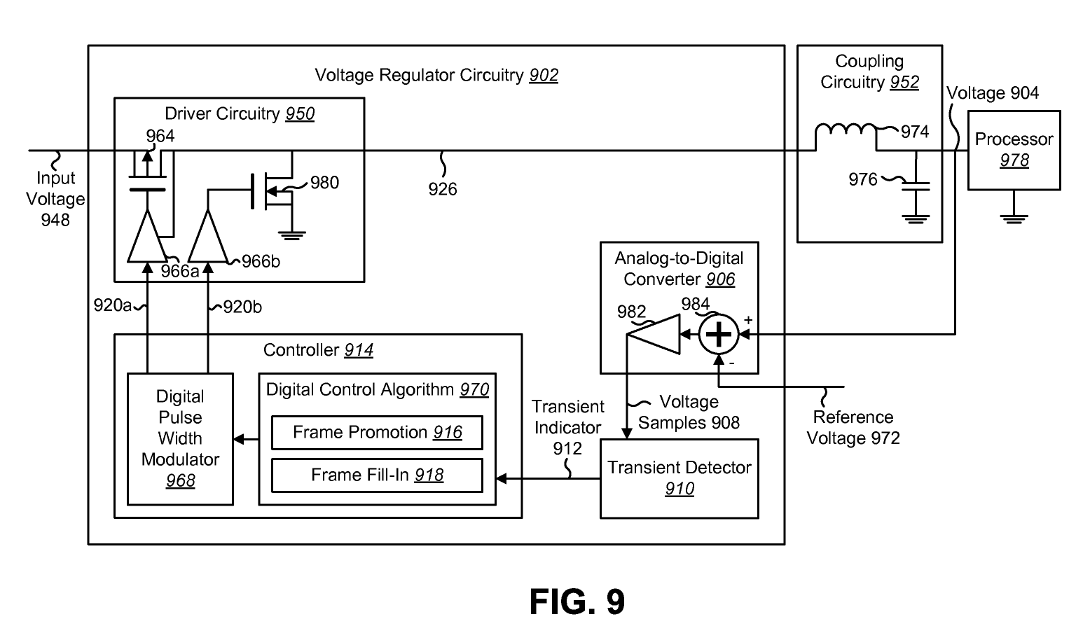

FIG. 9 is a block diagram illustrating one example of voltage regulator circuitry 902 for controlling a voltage 904 for a processor 978. The voltage regulator circuitry 902 may be one example of one or more of the circuitries 102, 602 described above. The voltage regulator circuitry 902 may be coupled to coupling circuitry 952 and may provide a voltage 904 to the processor 978 through the coupling circuitry 952. The voltage regulator circuitry 902 may also be coupled to the processor 978 (through the coupling circuitry). It should be noted that the term “couple” and variations thereof as used herein may indicate that a first component may be connected directly or indirectly (e.g., through another component) to a second component. In one configuration, the voltage regulator circuitry 902 and the coupling circuitry 952 may be a buck converter. In this example, the coupling circuitry 952 includes an inductor 974 and a capacitor 976. In other examples, the coupling circuitry 952 may include additional and/or alternative components. In some configurations, the voltage regulator circuitry 902 may be a switching regulator.

The voltage regulator circuitry 902 may supply a voltage 904 to the processor 978 through the coupling circuitry 952. The processor 978 (e.g., a general purpose single- or multi-chip microprocessor, special purpose microprocessor, microcontroller, programmable gate array, etc.) may have specific power supply requirements. For example, the processor 978 may require milliamps of current during an idle state and then may require amperes of current when an active process begins. This nearly instantaneous change in current may result in a dramatic voltage variation in the voltage 904 (e.g., a fast load transient). However, the processor 978 may require a voltage 904 that is within a specific range (e.g., plus or minus 40 millivolts (mV)). The systems and methods described herein may be applied to control the voltage 904 such that the voltage is maintained within the specific range.

As illustrated in FIG. 9, an analog-to-digital converter 906 may be coupled to the output of the coupling circuitry 952 that supplies the voltage 904 to the processor 978. The analog-to-digital converter 906 may include summer 984 to determine a voltage (e.g., error voltage) between the voltage 904 and a reference voltage 972 (e.g., a target or desired voltage). The analog-to-digital converter 906 may also include a comparator 982 for discretizing the difference voltage into voltage samples 908. In another configuration, the analog-to-digital converter 906 may be a window flash ADC. One example of a window flash ADC may include eight comparators at reference voltages 11 mV apart (at ±5.5 mV, ±16.5 mV, ±27.5 mV, and ±38.5 mV, for example). The analog-to-digital converter 906 may be clocked such that conversion occurs at an approximately constant rate (e.g., 10 megahertz (MHz)). The analog-to-digital converter 906 may be coupled to a transient detector 910. The transient detector 910 may produce a transient indicator 912 based on the voltage samples 908. For example, the transient detector 910 may operate similar to one or more of the transient detectors 610, 110 described above.

The controller 914 may receive the transient indicator 912 and may generate differential control signals 920a-b based on the transient indicator 912. The controller 914 may include a digital control algorithm 970 and a digital pulse width modulator 968.

The digital control algorithm 970 may include a frame promotion module 916. The digital control algorithm 970 may optionally include a frame fill-in module 918. The frame promotion module 916 may function similarly to one or more of the frame promotion modules 116, 616 described above. For example, the frame promotion module 916 may promote a frame as described in connection with FIGS. 1-8 above. The frame fill-in module 918 may function similarly to one or more of the frame fill-in modules 118, 618 described above. For example, the frame fill-in module 918 may perform frame fill-in as described in connection with FIGS. 1, 4, 5, 6, 7 and 8 above.

The digital pulse width modulator 968 may output pulse widths (e.g., on times) in the differential control signals 920a-b based on the output of the digital control algorithm 970. The digital pulse width modulator 968 may output differential control signals 920a-b that are approximate complements to (e.g., inverse to) each other. The differential control signals 920a-b may be provided to the driver circuitry 950.

The driver circuitry 950 may switch the input voltage 948 on to the coupling circuitry 952 and off from the coupling circuitry 952 (e.g., provide a switch signal 926 to the coupling circuitry 952) based on the differential control signals 920a-b. In this example, the driver circuitry 950 includes a p-type metal oxide semiconductor field effect transistor (MOSFET) 964, an n-type MOSFET 980, a first buffer 966a and a second buffer 966b. In some configurations, each buffer 966a-b may include four tapered inverters ranging from small to large, where each subsequent inverter is approximately three times larger than the previous inverter to constitute buffers 966a-b that can drive large output field effect transistors (FETs) 964, 980. The first buffer 966a drives the gate of the p-type MOSFET 964 based on the first differential control signal 920a. The p-type MOSFET 964 may serve to switch the input voltage 948 on when the first differential control signal 920a is high (e.g., during “on time”). In other words, the p-type MOSFET 964 may pull up the voltage regulator circuitry 902 output to the input voltage 948 when the first differential control signal 920a is high. The second buffer 966b drives the gate of the n-type MOSFET 980 based on the second differential control signal 920b. The n-type MOSFET 980 may serve to switch the input voltage 948 off when the second differential control signal 920b is high (e.g., during “off time”). In other words, the n-type MOSFET 980 may pull down the voltage regulator circuitry 902 output to ground when the second differential control signal 920b is high. Accordingly, the voltage supplied to the coupling circuitry 952 may vary according to the differential control signals 920a-b (e.g., the duty cycle).

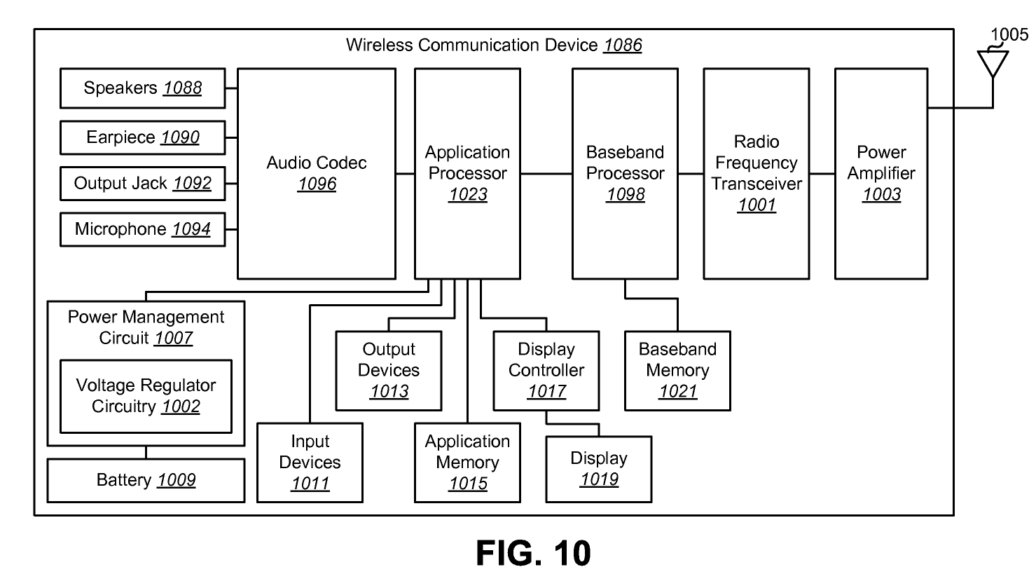

FIG. 10 is a block diagram illustrating one configuration of a wireless communication device 1086 in which systems and methods for controlling a voltage may be implemented. The wireless communication device 1086 may include an application processor 1023. The application processor 1023 generally processes instructions (e.g., runs programs) to perform functions on the wireless communication device 1086. The application processor 1023 may be coupled to an audio coder/decoder (codec) 1096.

The audio codec 1096 may be an electronic device (e.g., integrated circuit) used for coding and/or decoding audio signals. The audio codec 1096 may be coupled to one or more speakers 1088, an earpiece 1090, an output jack 1092 and/or one or more microphones 1094. The speakers 1088 may include one or more electro-acoustic transducers that convert electrical or electronic signals into acoustic signals. For example, the speakers 1088 may be used to play music or output a speakerphone conversation, etc. The earpiece 1090 may be another speaker or electro-acoustic transducer that can be used to output acoustic signals (e.g., speech signals) to a user. For example, the earpiece 1090 may be used such that only a user may reliably hear the acoustic signal. The output jack 1092 may be used for coupling other devices to the wireless communication device 1086 for outputting audio, such as headphones. The speakers 1088, earpiece 1090 and/or output jack 1092 may generally be used for outputting an audio signal from the audio codec 1096. The one or more microphones 1094 may be one or more acousto-electric transducers that convert an acoustic signal (such as a user's voice) into electrical or electronic signals that are provided to the audio codec 1096.

The application processor 1023 may also be coupled to a power management circuit 1007. One example of the power management circuit 1007 is a power management integrated circuit (PMIC), which may be used to manage the electrical power consumption of the wireless communication device 1086. It should be noted that the power management circuit 1007 may additionally or alternatively be coupled to one or more of the elements of the wireless communication device 1086 (besides the application processor 1023). The power management circuit 1007 may be coupled to a battery 1009. The battery 1009 may generally provide electrical power to the wireless communication device 1086.

The power management circuit 1007 may include voltage regulator circuitry 1002. The voltage regulator circuitry 1002 may be one example of one or more of the circuitries 102, 602, 902 described above. For instance, the voltage regulator circuitry 1002 may be used to regulate a voltage supplied to the application processor 1023 and/or other elements of the wireless communication device 1086.

The application processor 1023 may be coupled to one or more input devices 1011 for receiving input. Examples of input devices 1011 include infrared sensors, image sensors, accelerometers, touch sensors, keypads, etc. The input devices 1011 may allow user interaction with the wireless communication device 1086. The input devices 1011 may additionally or alternatively enable the wireless communication device 1086 to receive communications from other devices. Examples of input devices 1011 include wired ports, wireless ports, etc.

The application processor 1023 may also be coupled to one or more output devices 1013. Examples of output devices 1013 include printers, projectors, screens, haptic devices, etc. The output devices 1013 may allow the wireless communication device 1086 to produce output that may be experienced by a user. The output devices 1013 may additionally or alternatively enable the wireless communication device 1086 to communicate with other devices. For instance, the output devices 1013 may include wired ports, wireless ports, etc.

The application processor 1023 may be coupled to application memory 1015. The application memory 1015 may be any electronic device that is capable of storing electronic information. Examples of application memory 1015 include double data rate synchronous dynamic random access memory (DDRAM), synchronous dynamic random access memory (SDRAM), flash memory, etc. The application memory 1015 may provide storage for the application processor 1023. For instance, the application memory 1015 may store data and/or instructions for the functioning of programs that are run on the application processor 1023.

The application processor 1023 may be coupled to a display controller 1017, which in turn may be coupled to a display 1019. The display controller 1017 may be a hardware block that is used to generate images on the display 1019. For example, the display controller 1017 may translate instructions and/or data from the application processor 1023 into images that can be presented on the display 1019. Examples of the display 1019 include liquid crystal display (LCD) panels, light emitting diode (LED) panels, cathode ray tube (CRT) displays, plasma displays, etc.

The application processor 1023 may be coupled to a baseband processor 1098. The baseband processor 1098 generally processes communication signals. For example, the baseband processor 1098 may demodulate and/or decode (e.g., channel decode) received signals. Additionally or alternatively, the baseband processor 1098 may encode (e.g., channel encode) and/or modulate signals in preparation for transmission.

The baseband processor 1098 may be coupled to baseband memory 1021. The baseband memory 1021 may be any electronic device capable of storing electronic information, such as SDRAM, DDRAM, flash memory, etc. The baseband processor 1098 may read information (e.g., instructions and/or data) from and/or write information to the baseband memory 1021. Additionally or alternatively, the baseband processor 1098 may use instructions and/or data stored in the baseband memory 1021 to perform communication operations.

The baseband processor 1098 may be coupled to a radio frequency (RF) transceiver 1001. The RF transceiver 1001 may be coupled to a power amplifier 1003 and one or more antennas 1005. The RF transceiver 1001 may transmit and/or receive radio frequency signals. For example, the RF transceiver 1001 may transmit an RF signal using a power amplifier 1003 and one or more antennas 1005. The RF transceiver 1001 may also receive RF signals using the one or more antennas 1005.

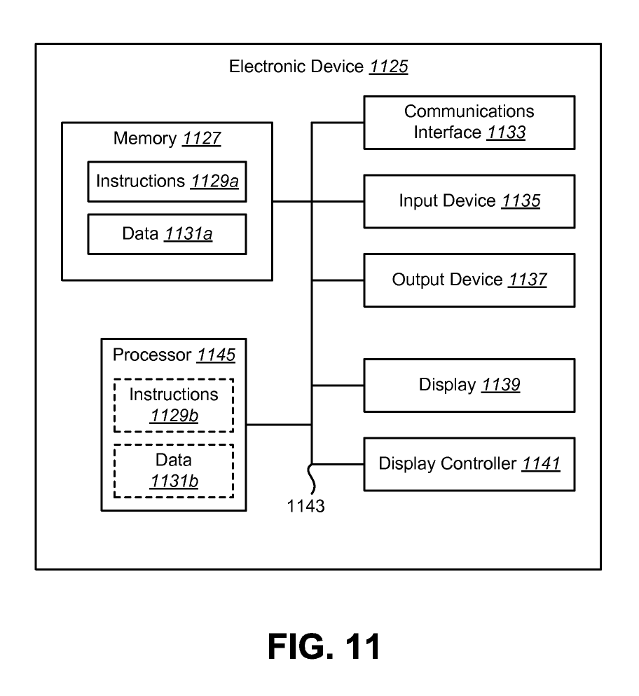

FIG. 11 illustrates various components that may be utilized in an electronic device 1125. The illustrated components may be located within the same physical structure or in separate housings or structures. Examples of electronic devices 1125 may include cellular phones, smartphones, computers, televisions, circuits, etc. The electronic device 1125 may be configured similarly to and/or perform one or more of the operations described in connection with one or more of the circuitries 102, 602, 902 described previously. The electronic device 1125 includes a processor 1145. The processor 1145 may be a general purpose single- or multi-chip microprocessor (e.g., an ARM), a special purpose microprocessor (e.g., a digital signal processor (DSP)), a microcontroller, a programmable gate array, etc. The processor 1145 may be referred to as a central processing unit (CPU). Although just a single processor 1145 is shown in the electronic device 1125 of FIG. 11, in an alternative configuration, a combination of processors (e.g., an ARM and DSP) could be used.

The electronic device 1125 also includes memory 1127 in electronic communication with the processor 1145. That is, the processor 1145 can read information from and/or write information to the memory 1127. The memory 1127 may be any electronic component capable of storing electronic information. The memory 1127 may be random access memory (RAM), read-only memory (ROM), magnetic disk storage media, optical storage media, flash memory devices in RAM, on-board memory included with the processor, programmable read-only memory (PROM), erasable programmable read-only memory (EPROM), electrically erasable PROM (EEPROM), registers, and so forth, including combinations thereof.

Data 1131a and instructions 1129a may be stored in the memory 1127. The instructions 1129a may include one or more programs, routines, sub-routines, functions, procedures, etc. The instructions 1129a may include a single computer-readable statement or many computer-readable statements. The instructions 1129a may be executable by the processor 1145 to implement one or more of the methods 200, 400, 700 described above. Executing the instructions 1129a may involve the use of the data 1131a that is stored in the memory 1127. FIG. 11 shows some instructions 1129b and data 1131b being loaded into the processor 1145 (which may come from instructions 1129a and data 1131a).

The electronic device 1125 may also include one or more communication interfaces 1133 for communicating with other electronic devices. The communication interfaces 1133 may be based on wired communication technology, wireless communication technology, or both. Examples of different types of communication interfaces 1133 include a serial port, a parallel port, a Universal Serial Bus (USB), an Ethernet adapter, an IEEE 1394 bus interface, a small computer system interface (SCSI) bus interface, an infrared (IR) communication port, a Bluetooth wireless communication adapter, an IEEE 802.11 wireless communication adapter and so forth.

The electronic device 1125 may also include one or more input devices 1135 and one or more output devices 1137. Examples of different kinds of input devices 1135 include a keyboard, mouse, microphone, remote control device, button, joystick, trackball, touchpad, lightpen, etc. Examples of different kinds of output devices 1137 include a speaker, printer, etc. One specific type of output device that may be typically included in an electronic device 1125 is a display device 1139. Display devices 1139 used with configurations disclosed herein may utilize any suitable image projection technology, such as a cathode ray tube (CRT), liquid crystal display (LCD), light-emitting diode (LED), gas plasma, electroluminescence, or the like. A display controller 1141 may also be provided, for converting data stored in the memory 1127 into text, graphics, and/or moving images (as appropriate) shown on the display device 1139.

The various components of the electronic device 1125 may be coupled together by one or more buses, which may include a power bus, a control signal bus, a status signal bus, a data bus, etc. For simplicity, the various buses are illustrated in FIG. 11 as a bus system 1143. It should be noted that FIG. 11 illustrates only one possible configuration of an electronic device 1125. Various other architectures and components may be utilized.

In the above description, reference numbers have sometimes been used in connection with various terms. Where a term is used in connection with a reference number, this may be meant to refer to a specific element that is shown in one or more of the Figures. Where a term is used without a reference number, this may be meant to refer generally to the term without limitation to any particular Figure.

The term “determining” encompasses a wide variety of actions and, therefore, “determining” can include calculating, computing, processing, deriving, investigating, looking up (e.g., looking up in a table, a database or another data structure), ascertaining and the like. Also, “determining” can include receiving (e.g., receiving information), accessing (e.g., accessing data in a memory) and the like. Also, “determining” can include resolving, selecting, choosing, establishing and the like.

The phrase “based on” does not mean “based only on,” unless expressly specified otherwise. In other words, the phrase “based on” describes both “based only on” and “based at least on.”

The functions described herein may be stored as one or more instructions on a processor-readable or computer-readable medium. The term “computer-readable medium” refers to any available medium that can be accessed by a computer or processor. By way of example, and not limitation, such a medium may comprise RAM, ROM, EEPROM, flash memory, CD-ROM or other optical disk storage, magnetic disk storage or other magnetic storage devices, or any other medium that can be used to store desired program code in the form of instructions or data structures and that can be accessed by a computer. Disk and disc, as used herein, includes compact disc (CD), laser disc, optical disc, digital versatile disc (DVD), floppy disk and Blu-ray® disc where disks usually reproduce data magnetically, while discs reproduce data optically with lasers. It should be noted that a computer-readable medium may be tangible and non-transitory. The term “computer-program product” refers to a computing device or processor in combination with code or instructions (e.g., a “program”) that may be executed, processed or computed by the computing device or processor. As used herein, the term “code” may refer to software, instructions, code or data that is/are executable by a computing device or processor.

Software or instructions may also be transmitted over a transmission medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of transmission medium.

The methods disclosed herein comprise one or more steps or actions for achieving the described method. The method steps and/or actions may be interchanged with one another without departing from the scope of the claims. In other words, unless a specific order of steps or actions is required for proper operation of the method that is being described, the order and/or use of specific steps and/or actions may be modified without departing from the scope of the claims.

It is to be understood that the claims are not limited to the precise configuration and components illustrated above. Various modifications, changes and variations may be made in the arrangement, operation and details of the systems, methods, and apparatus described herein without departing from the scope of the claims.

What is claimed is:

1. Circuitry configured for controlling a voltage, comprising:
a transient detector that detects a transient in a first frame; and
a controller coupled to the transient detector, wherein the controller determines a duty cycle during a period upon detection of the transient and promotes a second frame based on the period.

2. The circuitry of claim 1, wherein the first frame is truncated to promote the second frame.

3. The circuitry of claim 1, wherein the controller performs frame fill-in.

4. The circuitry of claim 3, wherein performing frame fill-in comprises generating a control signal based on the transient and the period.

5. The circuitry of claim 4, wherein generating the control signal based on the transient and the period comprises determining whether the transient is a decreasing transient or an increasing transient.

6. The circuitry of claim 5, wherein if the transient is a decreasing transient, then the controller generates an increase control signal corresponding to the period and driver circuitry controls an input voltage based on the increase control signal.

7. The circuitry of claim 5, wherein if the transient is an increasing transient, then the controller generates a decrease control signal corresponding to the period and driver circuitry controls an input voltage based on the decrease control signal.

8. The circuitry of claim 1, wherein the circuitry is coupled to coupling circuitry.

9. The circuitry of claim 1, wherein the circuitry controls the voltage for a processor.

10. The circuitry of claim 1, wherein the circuitry is a buck converter.

11. A method for controlling a voltage with circuitry, comprising:
detecting a transient in a first frame;
determining a duty cycle during a period upon detection of the transient; and
promoting a second frame based on the period.

12. The method of claim 11, wherein the first frame is truncated to promote the second frame.

13. The method of claim 11, wherein method further comprises performing frame fill-in.

14. The method of claim 13, wherein performing frame fill-in comprises generating a control signal based on the transient and the period.

15. The method of claim 14, wherein generating the control signal based on the transient and the period comprises determining whether the transient is a decreasing transient or an increasing transient.

16. The method of claim 15, wherein if the transient is a decreasing transient, then the method further comprises generating an increase control signal corresponding to the period and controlling an input voltage based on the increase control signal.

17. The method of claim 15, wherein if the transient is an increasing transient, then the method further comprises generating a decrease control signal corresponding to the period and controlling an input voltage based on the decrease control signal.

18. The method of claim 11, wherein the circuitry is coupled to coupling circuitry.

19. The method of claim 11, wherein the method controls the voltage for a processor.

20. The method of claim 11, wherein the circuitry is a buck converter.

21. A computer-program product for controlling a voltage, comprising a non-transitory tangible computer-readable medium having instructions thereon, the instructions comprising:
code for causing circuitry to detect a transient in a first frame;
code for causing the circuitry to determine a duty cycle during a period upon detection of the transient; and
code for causing the circuitry to promote a second frame based on the period.

22. The computer-program product of claim 21, wherein the first frame is truncated to promote the second frame.

23. The computer-program product of claim 21, wherein the instructions further comprise code for causing the circuitry to perform frame fill-in.

24. The computer-program product of claim 23, wherein performing frame fill-in comprises generating a control signal based on the transient and the period.

25. An apparatus for controlling a voltage, comprising:
means for detecting a transient in a first frame;
means for determining a duty cycle during a period upon detection of the transient; and
means for promoting a second frame based on the period.

26. The apparatus of claim 25, wherein the first frame is truncated to promote the second frame.

27. The apparatus of claim 25, further comprising means for performing frame fill-in.

28. The apparatus of claim 27, wherein performing frame fill-in comprises generating a control signal based on the transient and the period.
